(19) United States
(12) Patent Application Publication
(10) Pub. No.: US 2026/0344018 A1
(43) Pub. Date: Oct. 29, 2026

(54) SiC STEP TRENCH MOSFETS

(71) Applicant: Nami MOS CO., LTD., New Taipei City (TW)

(72) Inventors: Fu-Yuan HSIEH, New Taipei City (TW); Lin XU, Shanghai (CN)

(73) Assignee: Nami MOS CO., LTD., (omitted)

(21) Appl. No.: 19/189,435

(22) Filed: Apr. 25, 2025

(51) Int. Cl. H10D 84/00; H10D 62/10; H10D 62/832; H10D 64/00

(52) U.S. Cl. CPC H10D 84/144; H10D 62/109; H10D 62/127; H10D 62/8325; H10D 64/117

(57) ABSTRACT

A dual gate trench power device comprises a first MOSFET integrated with a super barrier rectifier (SBR) or with a second MOSFET in each unit cell, having a shielded gate electrode disposed in a step gate trench with different trench widths in upper and lower portions for cell pitch reduction. Specific on-resistance and reverse recovery time are thereby reduced with the improved structures.

### FIELD OF THE INVENTION

This invention generally relates to a unit cell structure of a wide band power semiconductor device such as Silicon Carbide (SiC) or Gallium Nitride (GaN) power devices having two types of gate trenches with a shielded gate electrode disposed in a step trench, and more particularly, to integrate a first trench Metal Oxide Semiconductor Field Effect Transistor (MOSFET) with a Super Barrier Rectifier (SBR) forming a SBR-MOSFET (SBRMOSFET) or with a second MOSFET forming a hybrid-channel MOSFET (HCMOSFET) to achieve a lower on-resistance, and a less switching loss. The novel device cell pitch can be shrunk because the step trench structure has a narrower trench width in an upper portion than in a lower portion of the step trench.

### BACKGROUND OF THE INVENTION

Because of their faster switching speed, higher temperature operation, and lower switching loss, SiC MOSFETs are very promising to replace Si super junction MOSFETs, and Si insulated gate bipolar transistors (IGBTs). However, a parasitic PIN body diode of the SiC MOSFET has a relatively higher turn-on voltage (~3 V) than its Si MOSFET counterpart (~0.7 V), owing to the wide band gap properties, which deteriorates reverse recovery characteristics. As a result, an external Schottky barrier diode (SBD) is normally used in power modules to inactivate the parasitic PIN diode. However, it was found that a parasitic inductance between the MOSFET and the external SBD has a great effect on the conduction power loss.

Various integrated devices are suggested and demonstrated to improve the characteristics of the parasitic PIN body diode in the SiC MOSFET. Among them, integrating with an SBD or a Junction barrier diode (JBSD) is widely adopted. However, a high-temperature reverse leakage current of the SBD is much larger than that of the parasitic PIN diode.

Therefore, there is still a need in the art of the SiC MOSFETs design and fabrication, to provide a novel cell structure, device configuration and manufacturing process that making an SGT MOSFET have a lower on-resistance and a lower switching loss.

### SUMMARY OF THE INVENTION

The present invention provides a SiC step trench MOSFET having a first type and a second type of gate trenches formed in an epitaxial layer. The first type of gate trench having a first type of step trench structure comprising a first top gate trench and at least one first bottom gate trench for the formation of a first gate electrode and a first grounded P-shield (PS) region for the gate oxide electric-field reduction, wherein the first gate electrode is disposed into the first top gate trench padded with a first gate oxide along sidewalls of the first top gate trench, and having a first thick oxide layer as a first insulating film on a bottom region of the first top gate trench, and the first grounded PS region is formed surrounding the at least one first bottom gate trench filled up with the first thick oxide layer, connecting with a first body region through the at least one grounded P (GP) region adjoining a portion of sidewalls of the first type of gate trench, and shorted with a source metal; The first grounded PS region having a Y-shape structure with multiple sub-PS regions forms a saturation current pitching (SCP) region with a second grounded PS region below a first body region for the short circuit capability enhancement. The first type of step trench structure has a larger width in the first top gate trench than in the at least one first bottom gate trench. A shielded gate electrode is disposed into the second type of gate trench and shorted to a source metal. The second type of gate trench is either a single vertical trench with sidewalls having an 85~90 degree angle with respect to the surface of the epitaxial layer. or a step trench that has a narrower trench width in the upper portion than in the lower portion.

According to another aspect, the invention features a power device comprising: a first type of gate trench for a SiC step trench MOSFET (STMOSFET) and a second type of gate trench for a SiC step trench SBR (STSBR); A shielded gate electrode of the SiC STSBR disposed into the second type of gate trench padded with a second gate oxide along sidewalls of an upper portion of the second type of gate trench, and with a second insulating film as a field oxide on a bottom region and along sidewalls of a lower portion of the second type of gate trench, wherein the second type of gate trench has a second type of step trench structure with a narrower trench width in the upper portion than in the lower portion of the second type of gate trench. A first channel region of the SiC STMOSFET formed in a first body region along the at least one sidewall of the first type of gate trench, and a second channel region of the SiC STSBR formed in a second body region along sidewalls of the upper portion of the second type of gate trench; The second gate oxide has a thickness thinner than that of the first gate oxide; and the SiC STSBR has a channel length shorter than that of the SiC STMOSFET. The present invention provides a SiC STMOSFET integrated with a SBR as a MOS-Channel diode having a short channel for reducing the switching loss. The integrated STSBR creates a low potential barrier for the majority carriers in the MOS channel, which is adjustable by the gate oxide thickness, the P body doping concentration and the channel length. The STSBR has a lower forward voltage Vf and a lower reverse leakage current Ir than the Schottky Barrier rectifier. Moreover, the STSBR has a better and reliable performance at elevated temperature than the SBD and JSBD.

According to another aspect, the invention features a power device further comprising a second SiC STMOSFET having a shielded gate electrode in a lower portion of the second type of gate trench to form a SiC hybrid-channel MOSFET (HCMOSFET) with the first SiC STMOSFET in the unit cell of the power device for the specific on-resistance reduction, wherein the HCMOSFET has two different threshold voltages formed by an additional short channel implantation in a channel region of the second SiC STMOSFET to improve the positive temperature coefficient for widening safe operating area (SOA) and reliability assurance operated at high temperatures.

According to another aspect, a metal/poly stack gate electrode is introduced in this invention for the first SiC STMOSFET to increase switching speed and to reduce specific on-resistance.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1A is a top view of a preferred embodiment for a trench semiconductor power device with square closed cells layout according to the present invention.

FIG. 1B is a cross-sectional view showing a preferred A1-A1’ cross section of FIG. 1A comprising two types of gate trenches with a single epitaxial layer, wherein the first type of gate trench has a one-step gate trench structure according to the present invention.

FIG. 1C is a cross-sectional view showing a preferred B1-B1’ cross section of FIG. 1A comprising two types of gate trenches with a single epitaxial layer, wherein the first type of gate trench has a one-step gate trench structure and an GP region is formed along a portion of a second trench sidewall of the first top gate trench according to the present invention.

FIG. 2A is a cross-sectional view showing another preferred A1-A1’ cross section of FIG. 1A comprising two types of gate trenches with a single epitaxial layer, wherein both the first type and second type of gate trenches have a one-step gate trench structure according to the present invention.

FIG. 2B is a cross-sectional view showing another preferred B1-B1’ cross section of FIG. 1A comprising two types of gate trenches with a single epitaxial layer, wherein both the first type and second type of gate trenches have a one-step gate trench structure and an GP region is formed along a portion of a second trench sidewall of the first top gate trench according to the present invention.

FIG. 3A is a top view of another preferred embodiment for a trench semiconductor power device comprising a trench MOSFET integrated with a SBR as a MOS-channel diode with square closed cells layout according to the present invention.

FIG. 3B is a cross-sectional view showing a preferred A2-A2’ cross section of FIG. 3A comprising a SiC MOSFET and a SiC SBR integrated in each unit cell, wherein the first type of gate trench has a one-step gate trench structure according to the present invention.

FIG. 3C is a cross-sectional view showing a preferred B2-B2’ cross section of FIG. 3A comprising a SiC MOSFET and a SiC SBR integrated in each unit cell, wherein the first type of gate trench has a one-step gate trench structure and an GP region is formed along a portion of a second trench sidewall of the first top gate trench according to the present invention.

FIG. 4A is a cross-sectional view showing another preferred A2-A2’ cross section of FIG. 3A comprising a SiC MOSFET and a SiC SBR integrated in each unit cell, wherein both the first and second type of gate trenches have a one-step gate trench structure according to the present invention.

FIG. 4B is a cross-sectional view showing another preferred B2-B2’ cross section of FIG. 3A comprising a SiC MOSFET and a SiC SBR integrated in each unit cell, wherein both the first and second type of gate trenches have a one-step gate trench structure and an GP region is formed along a portion of a second trench sidewall of the first top gate trench according to the present invention.

FIG. 5A is a cross-sectional view showing another preferred A2-A2’ cross section of FIG. 3A with two stepped epitaxial layers, wherein the doping concentration variations of the N type epitaxial layer as grown are depicted along the vertical direction according to the present invention.

FIG. 5B is a cross-sectional view showing another preferred A2-A2’ cross section of FIG. 3A with multiple stepped epitaxial (MSE) layers, wherein the doping concentration variations of the N type epitaxial layer as grown are depicted along the vertical direction according to the present invention.

FIG. 5C is a cross-sectional view showing another preferred A2-A2’ cross section of FIG. 3A with MSE layers, wherein the doping concentration variations of the N type epitaxial layer as grown are depicted along the vertical direction according to the present invention.

FIG. 5D is a cross-sectional view showing another preferred A2-A2’ cross section of FIG. 3A comprising electric field reducing regions surrounding bottom regions of the second type of gate trenches with MSE layers, wherein the doping concentration variations of the N type epitaxial layer as grown are depicted along the vertical direction according to the present invention.

FIG. 6A is a cross-sectional view showing another preferred A2-A2’ cross section of FIG. 3A comprising a first P-shield (PS) region surrounding a bottom of the first type of gate trench having a width greater than that of the first type of gate trench with two stepped epitaxial layers, wherein the doping concentration variations of the N type epitaxial layer as grown are depicted along the vertical direction according to the present invention.

FIG. 6B is a cross-sectional view showing another preferred B2-B2’ cross section of FIG. 3A comprising an GP region along a portion of a second trench sidewall of the first top gate trench connecting the first PS region to the first body region with two stepped epitaxial layers, wherein the doping concentration variations of the N type epitaxial layer as grown are depicted along the vertical direction according to the present invention.

FIG. 7A is a cross-sectional view showing another preferred A2-A2’ cross section of FIG. 3A comprising a first P-shield (PS) region surrounding a bottom of the first type of gate trench having a width greater than that of the first type of gate trench with two stepped epitaxial layers, wherein the doping concentration variations of the N type epitaxial layer as grown are depicted along the vertical direction according to the present invention

FIG. 7B is a cross-sectional view showing another preferred B2-B2’ cross section of FIG. 3A comprising an GP region along a portion of a second trench sidewall of the first top gate trench connecting the first PS region to the first body region with two stepped epitaxial layers, wherein the doping concentration variations of the N type epitaxial layer as grown are depicted along the vertical direction according to the present invention.

FIG. 8 is a cross-sectional view showing another preferred A2-A2’ cross section of FIG. 3A comprising a second P-shield (Pr) region adjoining a lower surface of the first body region with two stepped epitaxial layers, wherein the doping concentration variations of the N type epitaxial layer as grown are depicted along the vertical direction according to the present invention.

FIG. 9A is a cross-sectional view showing another preferred A2-A2’ cross section of FIG. 3A comprising a second P-shield (Pr) region adjoining a lower surface of the first body region forming a saturation current pitching (SCP) region with the first PS region having a Y-shape structure with two stepped epitaxial layers, wherein the doping concentration variations of the N type epitaxial layer as grown are depicted along the vertical direction according to the present invention.

FIG. 9B is a cross-sectional view showing another preferred A2-A2’ cross section of FIG. 3A comprising a Metal/poly stack gate electrode in the first type of gate trench with two stepped epitaxial layers, wherein the doping concentration variations of the N type epitaxial layer as grown are depicted along the vertical direction according to the present invention.

FIG. 10A is a top view of another preferred embodiment for a trench semiconductor power device comprising a second MOSFET integrated with a first MOSFET to form a hybrid-channel MOSFET (HCMOSFET) with stripe cells layout according to the present invention.

FIG. 10B is a cross-sectional view showing a preferred A3-A3’ cross section of FIG. 10A comprising a second MOSFET integrated with a first MOSFET to form a HCMOSFET with two stepped epitaxial layers, wherein the doping concentration variations of the N type epitaxial layer as grown are depicted along the vertical direction according to the present invention.

FIG. 10C is a cross-sectional view showing another preferred A3-A3’ cross section of FIG. 10A comprising a second MOSFET integrated with a first MOSFET to form a HCMOSFET with a second short channel implant (SCI2) region surrounding the second channel region, wherein the doping concentration variations of the N type epitaxial layer as grown are depicted along the vertical direction according to the present invention.

FIG. 11A is a cross-sectional view showing another preferred A3-A3’ cross section of FIG. 10A comprising a second MOSFET integrated with a first MOSFET to form a HCMOSFET with a first PS region surrounding a bottom of the first type of gate trench having a width greater than that of the first type of gate trench, wherein the doping concentration variations of the N type epitaxial layer as grown are depicted along the vertical direction according to the present invention.

FIG. 11B is a cross-sectional view showing another preferred A3-A3’ cross section of FIG. 10A comprising a second MOSFET integrated with a first MOSFET to form a HCMOSFET with a second short channel implant (SCI2) region surrounding the second channel region, wherein the doping concentration variations of the N type epitaxial layer as grown are depicted along the vertical direction according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

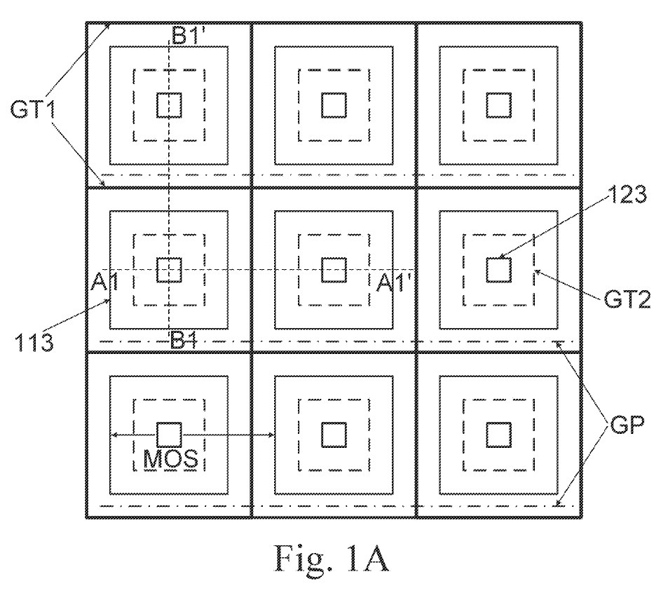

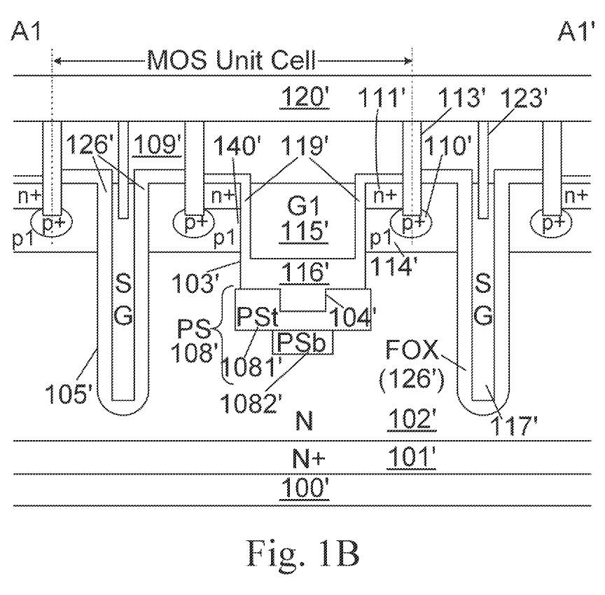

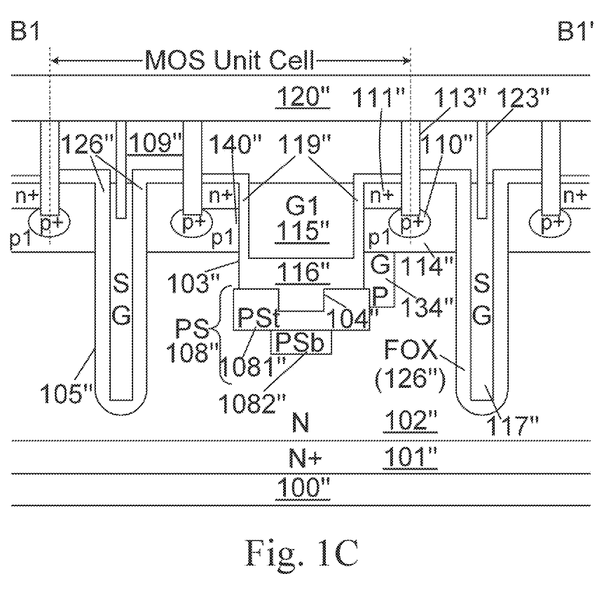

Please refer to FIG. 1A for a top view of a preferred embodiment for a trench semiconductor power device comprising a plurality of unit cells with each unit cell comprising two types of gate trenches. Each of the unit cells has a first type of gate trench (GT1, as illustrated) with a square shape surrounds a second type of gate trench (GT2, as illustrated). The GT2 has a square shape surrounding a shielded gate contact trench 123. Moreover, a source contact trench 113 with a square shape is formed between GT1 and GT2, and a MOS unit cell region is formed between the source contact trenches 113 of the two adjacent unit cells. According to the present invention, grounded P (GP, as illustrated) regions are formed surrounding a portion of sidewalls of the GT1 in each unit cell.

Please refer to FIG. 1B for a cross-sectional view showing a preferred embodiment along A1-A1’ line of FIG. 1A with a single epitaxial layer according to the present invention. The preferred embodiment comprises an N-channel SGT MOSFET formed in an N type epitaxial layer 102’ onto an N+ substrate 101’ coated with a back metal 100’ on rear side as a drain metal, wherein the power device in the present invention comprises two types of gate trenches in each MOS unit cell. Inside the N type epitaxial layer 102’, a plurality of first type of gate trenches and second type of gate trenches 105’ are formed vertically downward from a top surface of the N type epitaxial layer 102’ and not reaching the common interface between the N type epitaxial layer 102’ and the N+ substrate 101’, wherein the second type of gate trench 105’ has a trench depth deeper than that of the first type of gate trench. The first type of gate trench has a one-step gate trench structure comprising a first top gate trench 103’ and a first bottom gate trench 104’, wherein the first top gate trench 103’ is above the first bottom gate trench 104’, with a gate width wider than that of the first bottom gate trench 104’. A first gate electrode (G1, as illustrated) 115’ is disposed in the first top gate trench 103’ and surrounded with a thick bottom oxide as a first insulating film 116’ on a bottom region of the first top gate trench 103’, and surrounded with a first gate oxide (GOX1) 119’ on sidewalls of the first top gate trench 103’, wherein the first insulating film 116’ has a greater thickness than the GOX1 119’. The first bottom gate trench 104’ is filled up with the first insulating film 116’. While a shielded gate electrode (SG, as illustrated) 117’ is formed inside each of the second type of gate trenches 105’, and surrounded with a second insulating film as a field oxide (FOX, as illustrated) 126’ on a bottom region and along sidewalls of the second type of gate trenches 105’, wherein the FOX 126’ has a thickness greater than that of the GOX1 119’. Between the first type and second type of gate trenches, a first p (p1, as illustrated) body region 114’ with a first n+ source region 111’ thereon is extending at a top surface of the N type epitaxial layer 102’ and surrounding the G1 115’ padded by the GOX1 119’, wherein a p+ body contact region 110’ is formed below the first n+ source regions 111’ in the p1 body regions 114’ to reduce the body contact resistance. A first channel region 140’ of the MOSFET is formed in the p1 body region 114’ along sidewalls of the first top gate trench 103’ connecting to the first source region 111’. An interlayer dielectric film 109’ is stacked on the epitaxial layer 102’, and a source metal 120’ is formed onto the interlayer dielectric film 109’. The p1 body regions 114’ and the first n+ source regions 111’, and the SG 117’ are shorted to the source metal 120’ through a plurality of source contact trenches 113’ and shielded gate contact trenches 123’, respectively, wherein the source contact trenches 113’ and the shielded gate contact trenches 123’ are filled with contact metal plugs and metal barriers, and the source contact trenches 113’ are surrounded by the p+ heavily doped regions 110’ around bottoms underneath the first n+ source regions 111’. Moreover, a first P-shield (PS, as illustrated) region 108’ with a Y-shape structure for the gate oxide electric-field reduction is formed surrounding the first bottom gate trench 104’ comprising two sub-PS regions including a first top PS (PSt, as illustrated) region 1081’ and a first bottom PS (PSb, as illustrated) region 1082’, wherein the PSb region 1082’ is below the PSt region 1081’, with a lower doping concentration than the PSt region 1081’.

Please refer to FIG. 1C for a cross-sectional view showing a preferred embodiment along B1-B1’ line of FIG. 1A with a single epitaxial layer according to the present invention. The N-channel trenched semiconductor power device has a similar structure to FIG. 1B, except that the present invention further comprises a grounded P (GP, as illustrated) region 134’’ of a second conductivity type formed along a portion of the right-hand side sidewall of the first top gate trench 103’’ to ground the first PS region 108’’ to a source metal 120’’ through the p1 body region 114’’ and the source contact trench 113’’ for the gate oxide electric field reduction.

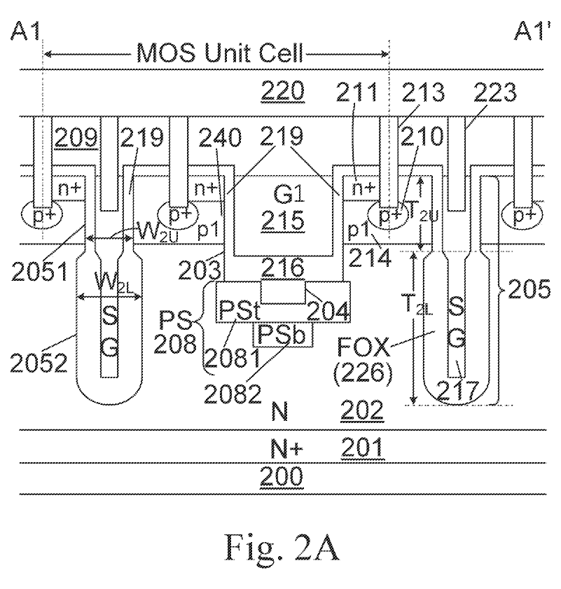

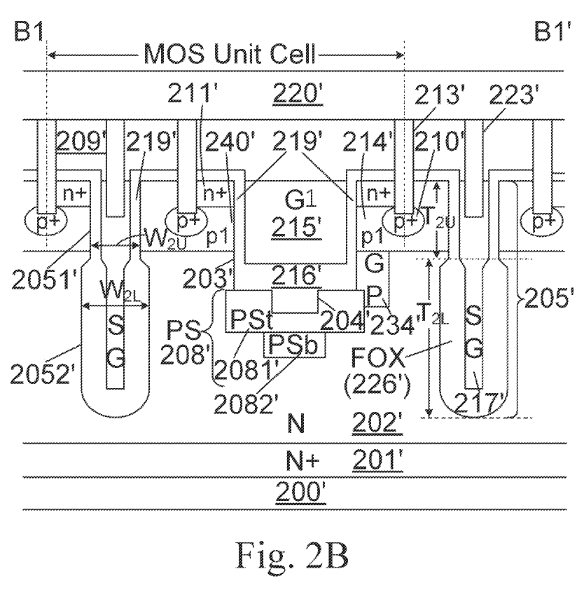

Please refer to FIG. 2A for a cross-sectional view showing another preferred embodiment along A1-A1’ line of FIG. 1A with a single epitaxial layer according to the present invention. The N-channel trenched semiconductor power device has a similar structure to FIG. 1B, except for the different gate trench structure in the second type of gate trenches 205. In the present invention, each of the second type of gate trenches 205 has a one-step gate trench structure comprising a second top gate trench 2051 with a trench depth T_{2U} and a second bottom gate trench 2052 with a trench depth T_{2L}, wherein the second top gate trench 2051 is above the second bottom gate trench 2052, with a trench width W_{2U} less than a trench width W_{2L} of the second bottom gate trench 2052. A shielded gate electrode (SG, as illustrated) 207 is formed in each of the second type of gate trenches 205 and surrounded with a second insulating film as a field oxide (FOX, as illustrated) 226 on a bottom region and along sidewalls of the second bottom gate trench 2052 and with GOX1 219 along sidewalls of the second top gate trench 2041, wherein the FOX 226 has a thickness greater than that of the GOX1 219. According to the present invention, the FOX 226 is formed by Local Oxidation of Silicon (LOCOS). During the LOCOS process, sidewalls of the second top gate trench 2051 are padded with either a silicon nitride layer or a two-layer stack of silicon nitride and silicon oxide to prevent the sidewalls from oxidation.

Please refer to FIG. 2B for a cross-sectional view showing another preferred embodiment along B1-B1’ line of FIG. 1A with a single epitaxial layer according to the present invention. The N-channel trenched semiconductor power device has a similar structure to FIG. 2A, except that the present invention further comprises a grounded P (GP, as illustrated) region 234’ of a second conductivity type formed along a portion of the right-hand sidewall of the first top gate trench 203’ to ground the first PS region 208’ to a source metal 220’ through the p1 body region 214’ and the source contact trench 213’ for the gate oxide electric field reduction.

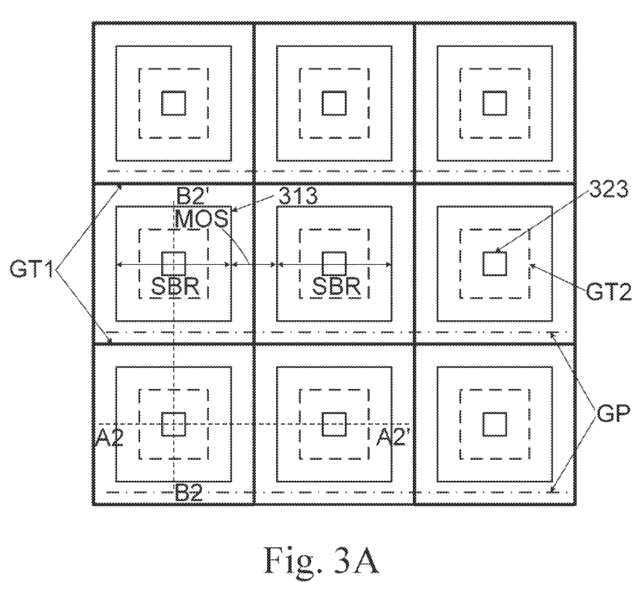

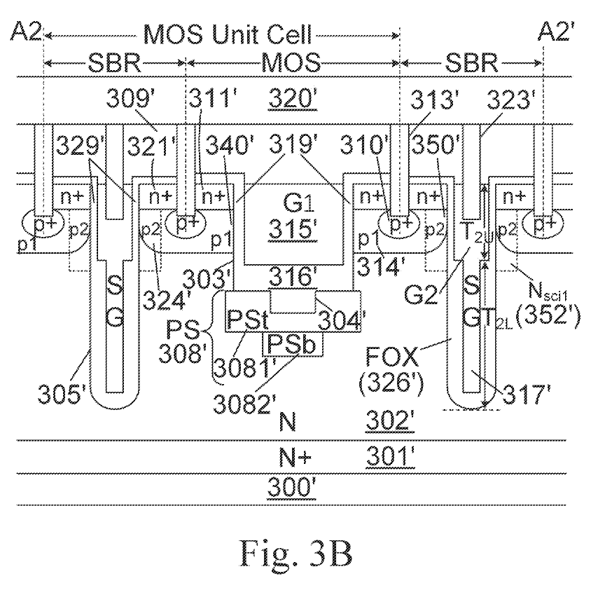

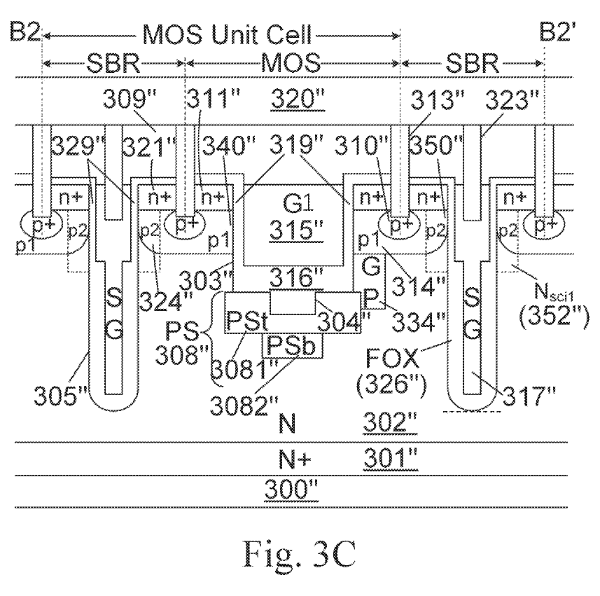

Please refer to FIG. 3A for a top view of another preferred embodiment for a trench semiconductor power device comprising a plurality of unit cells with each unit cell comprises two types of gate trenches. The power device has a similar structure to FIG. 1A, except that each unit cell in the present invention further comprises a super barrier rectifier (SBR, as illustrated) integrated with the MOSFET (MOS, as illustrated), and the SBR comprises a shielded gate contact 323 and a second type of gate trench (GT2, as illustrated) between the two adjacent source contact trenches 313 in each unit cell, while the MOS comprises a first type of gate trench (GT1, as illustrated) between the two source contact trenches 313 of the two adjacent unit cells. According to this invention, the MOS region surrounds the SBR region, and grounded P (GP, as illustrated) regions are formed surrounding a portion of sidewalls of the GT1 in each unit cell.

Please refer to FIG. 3B for a cross-sectional view showing a preferred embodiment along A2-A2’ line of FIG. 3A with a single epitaxial layer according to the present invention. The N-channel trenched semiconductor power device has a similar structure to FIG. 1B, except for the different gate trench structure in the second type of gate trench 305’ to form a super barrier rectifier (SBR, as illustrated) region. According to this invention, a SBR region is integrated with the first MOSFET (MOS, as illustrated) in each unit cell. The present invention in FIG. 3B further comprises a second p body (p2, as illustrated) region 324’ of a second conductivity type having a second n+ source region 321’ of a first conductivity type thereon, wherein the p2 body region 324’ has a doping concentration lower than that of the p1 body region 314’. A second channel region 350’ of the SBR region is thus formed in the p2 body region 324’ along sidewalls of an upper portion of the second type of gate trench 305’, connecting to the second n+ source region 321’, and the second channel region 350’ has a channel length shorter than that of the first channel region 340’. Moreover, an N type first short channel implant (Nsci1, as illustrated) region 352’ is formed surrounding the second channel region 350’ by Arsenic or Phosphorus angle implantation along sidewalls of the upper portion of the second type of gate trench 305’, and having a doping concentration higher than that of the N type epitaxial layer 302’. Moreover, a shielded gate electrode (SG, as illustrated) 317’ is formed in each of the second type of gate trenches 305’ and surrounded with a second gate oxide (GOX2) 329’ along sidewalls of an upper portion of the second type of gate trench 305’, and with a second insulating film as a field oxide (FOX, as illustrated) 326’ along a lower portion of the second type of gate trench 305’, wherein the GOX2 329’ has a thickness less that of the GOX1 319’, and the FOX 326’ has a thickness greater than that of the GOX1 319’.

Please refer to FIG. 3C for a cross-sectional view showing a preferred embodiment along B2-B2’ line of FIG. 3A with a single epitaxial layer according to the present invention. The N-channel trenched semiconductor power device has a similar structure to FIG. 3B, except that the present invention further comprises a grounded P (GP, as illustrated) region 334’’ of a second conductivity type formed along a portion of the right-hand sidewall of the first top gate trench 303’’ to ground the first PS region 308’’ to a source metal 320’’ through the p1 body region 314’’ and the source contact trench 313’’ for the gate oxide electric field reduction.

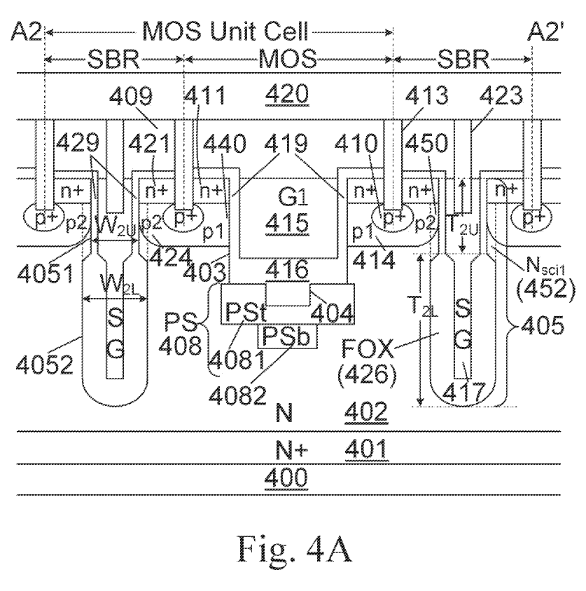

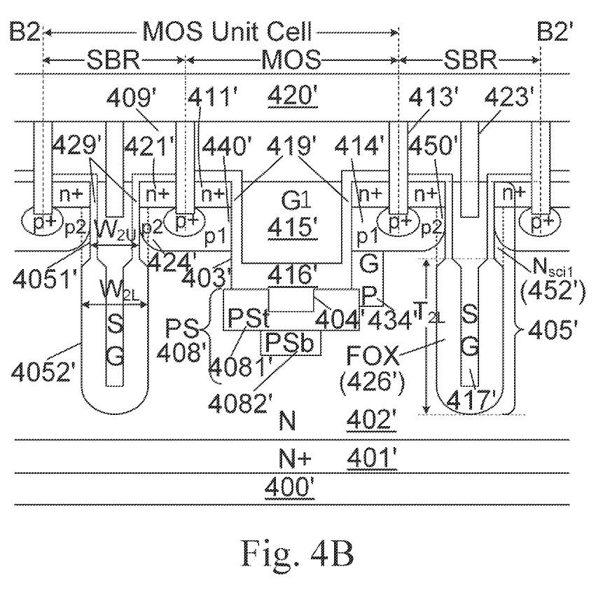

Please refer to FIG. 4A for a cross-sectional view showing another preferred embodiment along A2-A2’ line of FIG. 3A with a single epitaxial layer according to the present invention. The N-channel trenched semiconductor power device has a similar structure to FIG. 3B, except for the different gate trench structure in the second type of gate trenches 405. In the present invention, each of the second type of gate trenches 405 has a one-step gate trench structure comprising a second top gate trench 4051 with a trench depth T_{2U} and a second bottom gate trench 4052 with a trench depth T_{2L}, wherein the second top gate trench 4051 is above the second bottom gate trench 4052 with a trench width W_{2U} less than a trench width W_{2L} of the second bottom gate trench 4052. A shielded gate electrode (SG, as illustrated) 417 is formed in each of the second type of gate trenches 405 and surrounded with a second insulating film a field oxide (FOX, as illustrated) 426 on a bottom region and along sidewalls of the second bottom gate trench 4052 and with a second gate oxide (GOX2) 429 along sidewalls of the second top gate trench 4051, wherein the FOX 426 has a thickness greater than that of the first gate oxide (GOX1) 419, and thickness of the GOX1 419 is greater than that of the GOX2 429. According to the present invention, the FOX 426 is formed by Local Oxidation of Silicon (LOCOS). During the LOCOS process, sidewalls of the second top gate trench 4051 are padded with either a silicon nitride layer or a two-layer stack of silicon nitride and silicon oxide to prevent the sidewalls from oxidation.

Please refer to FIG. 4B for a cross-sectional view showing another preferred embodiment along B2-B2’ line of FIG. 3A with a single epitaxial layer according to the present invention. The N-channel trenched semiconductor power device has a similar structure to FIG. 4A, except that the present invention further comprises a grounded P (GP, as illustrated) region 434’ of a second conductivity type formed along a portion of the right-hand sidewall of the first top gate trench 403’ to ground the first PS region 408’ to a source metal 420’ through the p1 body region 414’ and the source contact trench 413’ for the gate oxide electric field reduction.

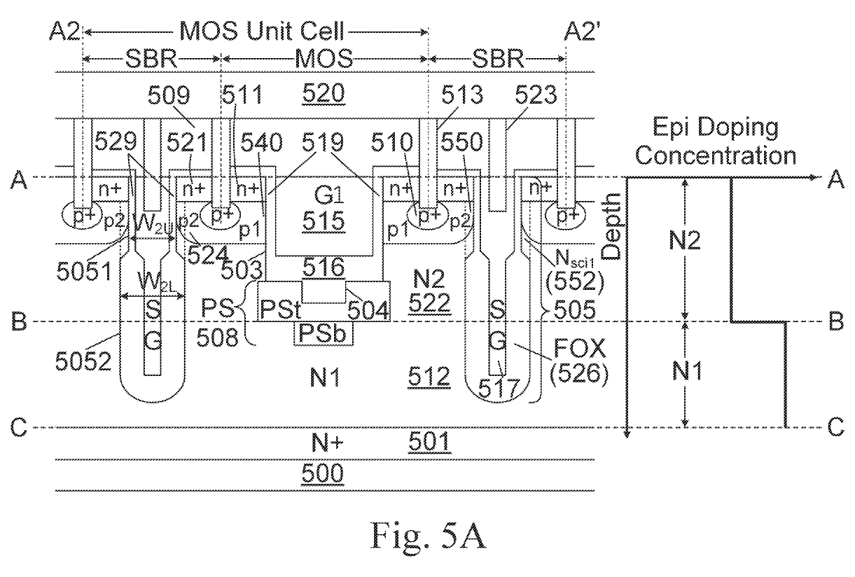

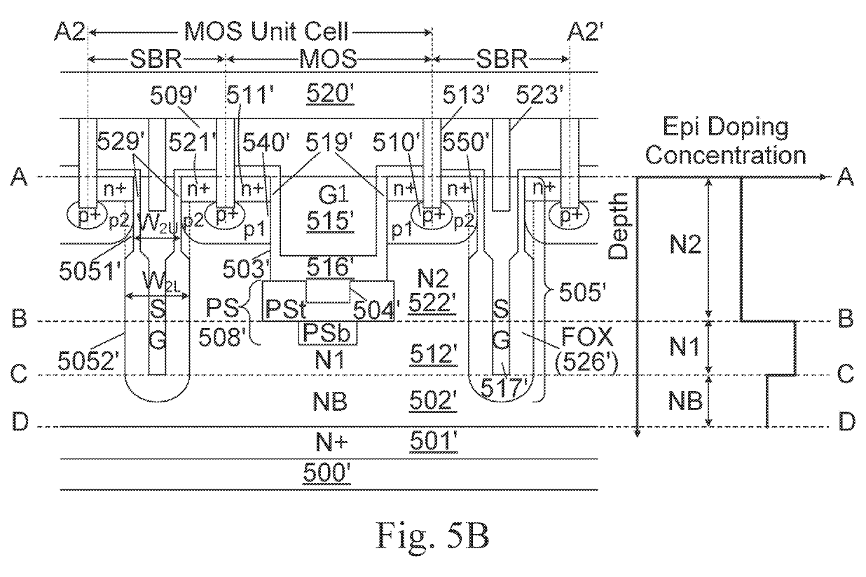

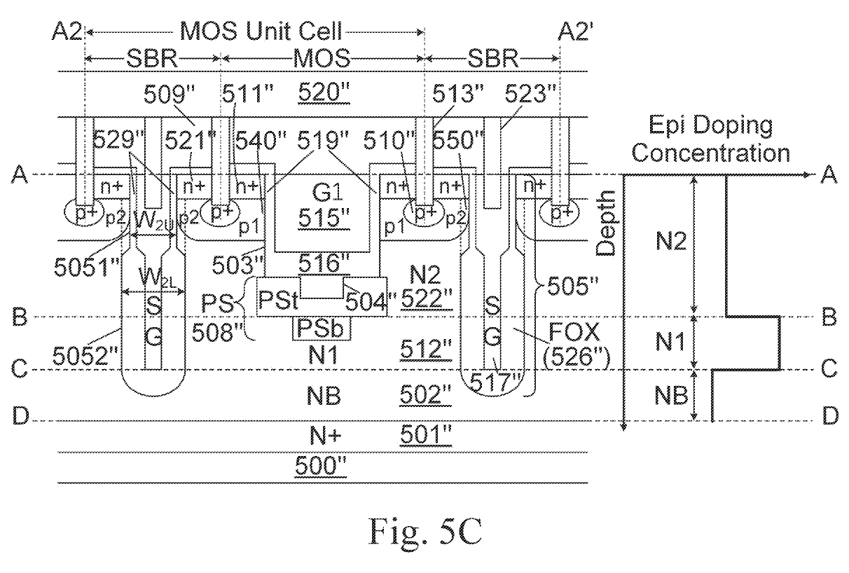

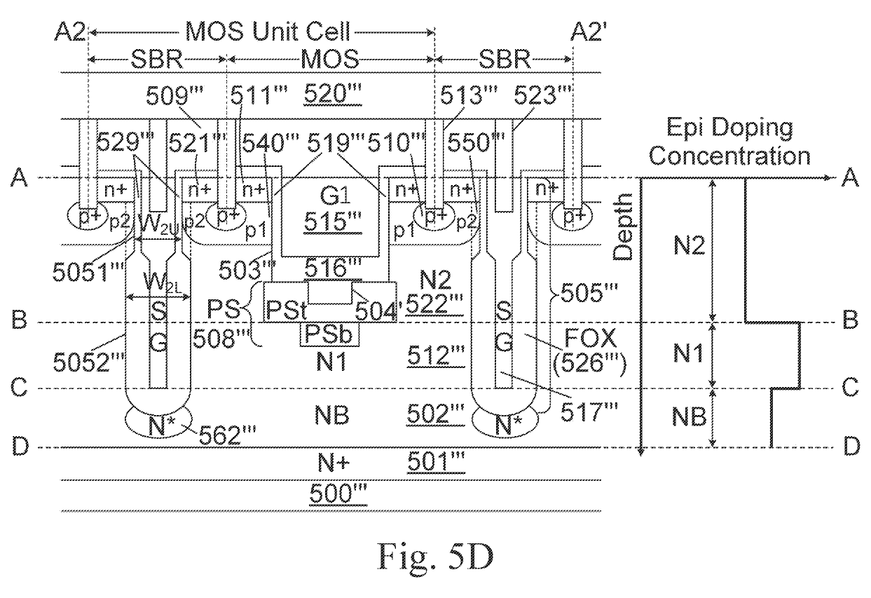

Please refer to FIG. 5A for a cross-sectional view showing another preferred embodiment along A2-A2’ line of FIG. 3A with a new and improved device structure having two stepped epitaxial layers wherein the doping concentration variations are depicted along the vertical direction according to the present invention. The N-channel trenched semiconductor power device has a similar structure to FIG. 4A, except that, the N type epitaxial layer in the present invention comprises two stepped epitaxial layers of different doping concentration including a bottom 1^{st} epitaxial layer (N1, as illustrated between B-B and C-C lines) 512 a with doping concentration D1 and a top 2^{nd} epitaxial layer (N2, as illustrated between A-A and B-B lines) 522 with a doping concentration D2, wherein D2< D1, to further reduce the specific on-resistance.

Please refer to FIG. 5B for a cross-sectional view showing another preferred embodiment along A2-A2’ line of FIG. 3A with a new and improved device structure having three stepped epitaxial layers wherein the doping concentration variations are depicted along the vertical direction according to the present invention. The N-channel trenched semiconductor power device has a similar structure to FIG. 5A, except that, the present invention further comprises a buffer epitaxial layer (NB, as illustrated) 502’ between a bottom of the shielded gate electrode (SG, as illustrated) 517’ and the N+ substrate 501’ with a doping concentration DB, wherein D2<DB<D1.

Please refer to FIG. 5C for a cross-sectional view showing another preferred embodiment along A2-A2’ line of FIG. 3A with a new and improved device structure having three stepped epitaxial layers wherein the doping concentration variations are depicted along the vertical direction according to the present invention. The N-channel trenched semiconductor power device has a similar structure to FIG. 5A, except that, the N type epitaxial layer in the present invention further comprises a buffer epitaxial layer (NB, as illustrated) 502’’ between a bottom of the shielded gate electrode (SG, as illustrated) 517’’ and the N+ substrate 501’’ with a doping concentration DB, wherein DB<D2< D1.

Please refer to FIG. 5D for a cross-sectional view showing another preferred embodiment along A2-A2’ line of FIG. 3A with a new and improved device structure having three stepped epitaxial layers wherein the doping concentration variations are depicted along the vertical direction according to the present invention. The N-channel trenched semiconductor power device has a similar structure to FIG. 5B, except that, the present invention further comprises an N type electric field reducing (N*, as illustrated) region 562’’’ formed surrounding a bottom region of the second type of gate trench 504’’’ with a doping concentration lower than a doping concentration DB of the NB region 502’’’.

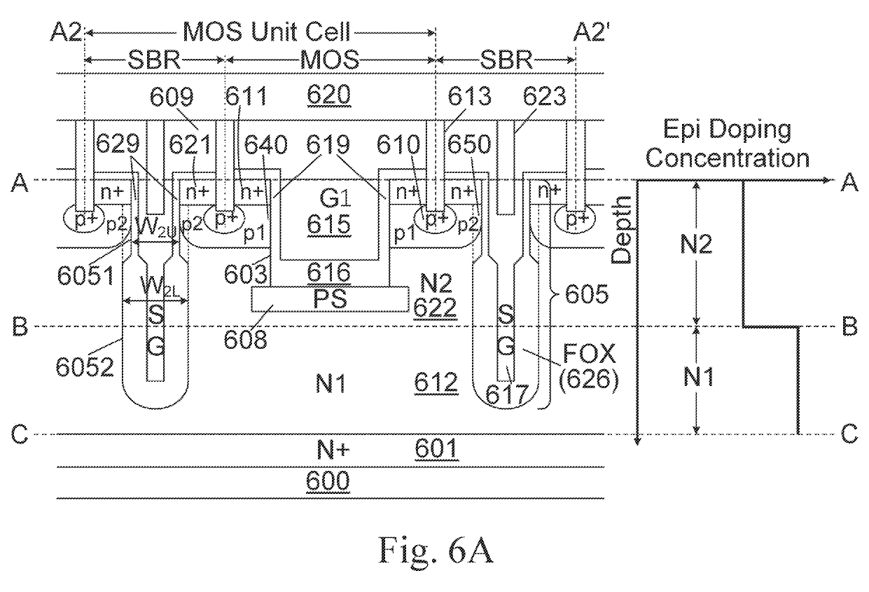

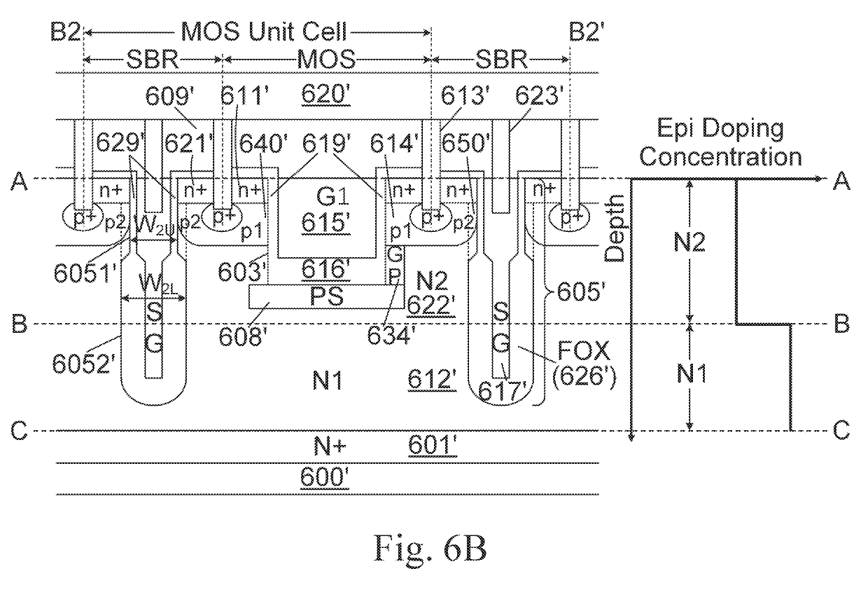

Please refer to FIG. 6A for a cross-sectional view showing another preferred embodiment along A2-A2’ line of FIG. 3A with a new and improved device structure having two stepped epitaxial layers wherein the doping concentration variations are depicted along the vertical direction according to the present invention. The N-channel trenched semiconductor power device has a similar structure to FIG. 5A, except that the first type of gate trench in the present invention comprises one single gate trench 603, and a first P-shield (PS, as illustrated) region 608 is formed surrounding a bottom of the first type of gate trench 603 with a width greater than that of the first type of gate trench 603.

Please refer to FIG. 6B for a cross-sectional view showing another preferred embodiment along B2-B2’ line of FIG. 3A with a single epitaxial layer according to the present invention. The N-channel trenched semiconductor power device has a similar structure to FIG. 6A, except that the present invention further comprises a grounded P (GP, as illustrated) region 634’ of a second conductivity type formed along a portion of the right-hand sidewall of the first type of gate trench 603’ to ground the first PS region 608’ to a source metal 620’ through the p1 body region 614’ and the source contact trench 613’ for the gate oxide electric field reduction.

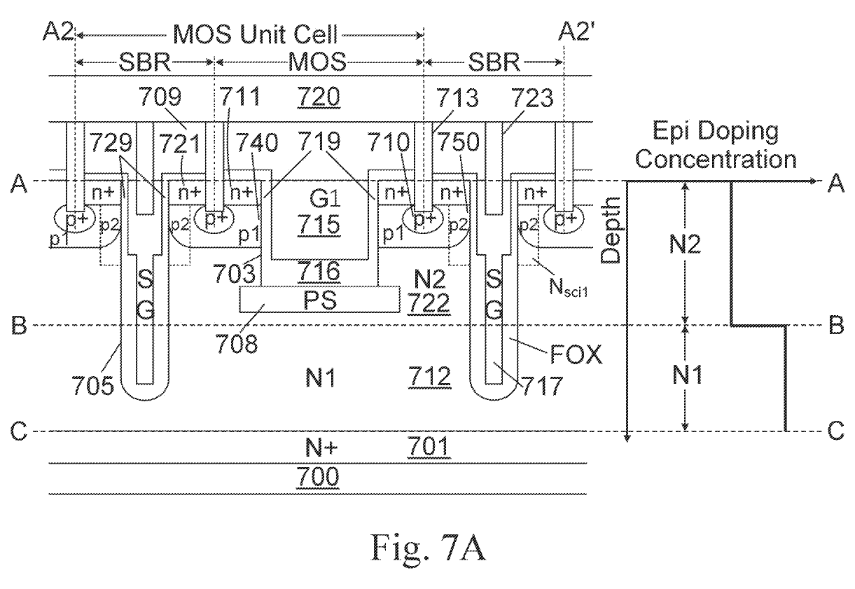

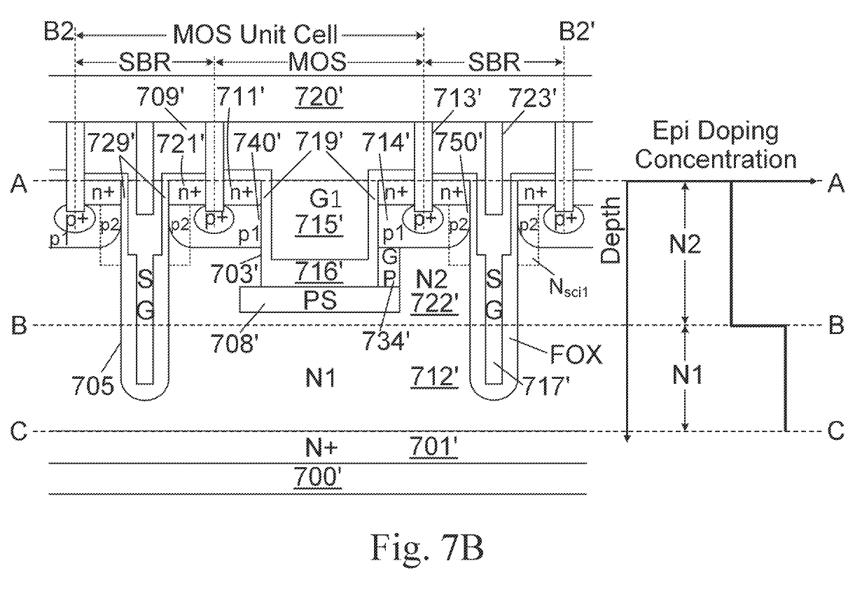

Please refer to FIG. 7A for a cross-sectional view showing another preferred embodiment along A2-A2’ line of FIG. 3A with a new and improved device structure having two stepped epitaxial layers wherein the doping concentration variations are depicted along the vertical direction according to the present invention. The N-channel trenched semiconductor power device has a similar structure to FIG. 3B, except that the first type of gate trench in the present invention comprises one single gate trench 703, and a first P-shield (PS, as illustrated) region 708 is formed surrounding a bottom of the first type of gate trench 703 with a width greater than that of the first type of gate trench 703. Moreover, the N type epitaxial layer in the present invention comprises two stepped epitaxial layers of different doping concentration including a bottom 1^{st} epitaxial layer (N1, as illustrated between B-B and C-C lines) 712 a with doping concentration D1 and a top 2^{nd} epitaxial layer (N2, as illustrated between A-A and B-B lines) 722 with a doping concentration D2, wherein D2< D1, to further reduce the specific on-resistance.

Please refer to FIG. 7B for a cross-sectional view showing another preferred embodiment along B2-B2’ line of FIG. 3A with two stepped epitaxial layers according to the present invention. The N-channel trenched semiconductor power device has a similar structure to FIG. 7A, except that the present invention further comprises a grounded P (GP, as illustrated) region 734’ of a second conductivity type formed along a portion of the right-hand sidewall of the first type of gate trench 703’ to ground the first PS region 708’ to a source metal 720’ through the p1 body region 714’ and the source contact trench 713’ for the gate oxide electric field reduction.

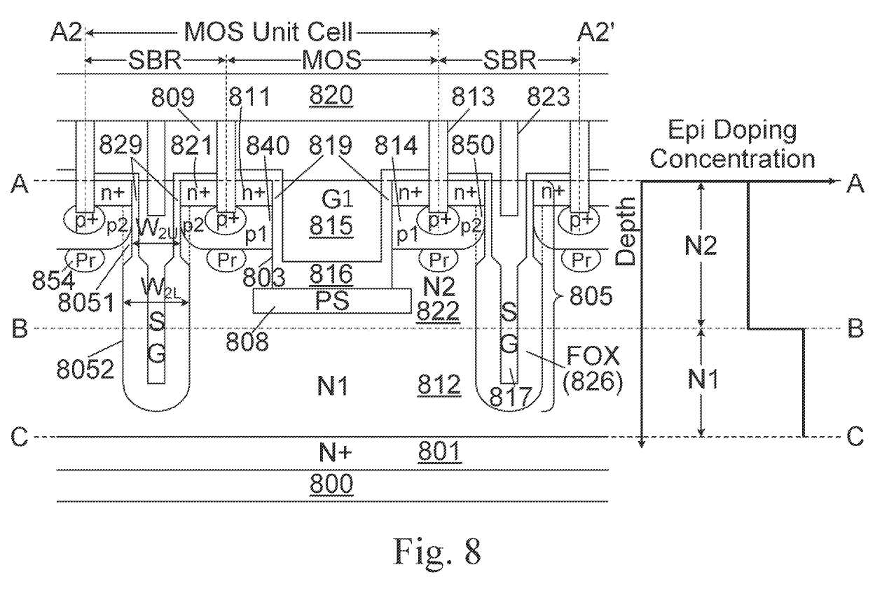

Please refer to FIG. 8 for a cross-sectional view showing another preferred embodiment along A2-A2’ line of FIG. 3A with a new and improved device structure having two stepped epitaxial layers wherein the doping concentration variations are depicted along the vertical direction according to the present invention. The N-channel trenched semiconductor power device has a similar structure to FIG. 6A, except that the present invention further comprises p type gate oxide electric field reducing (Pr, as illustrated) regions 954 as the second P-shield regions adjoining lower surfaces of the p1 body regions 914 and being apart from the first type and second type of gate trenches 903 and 905.

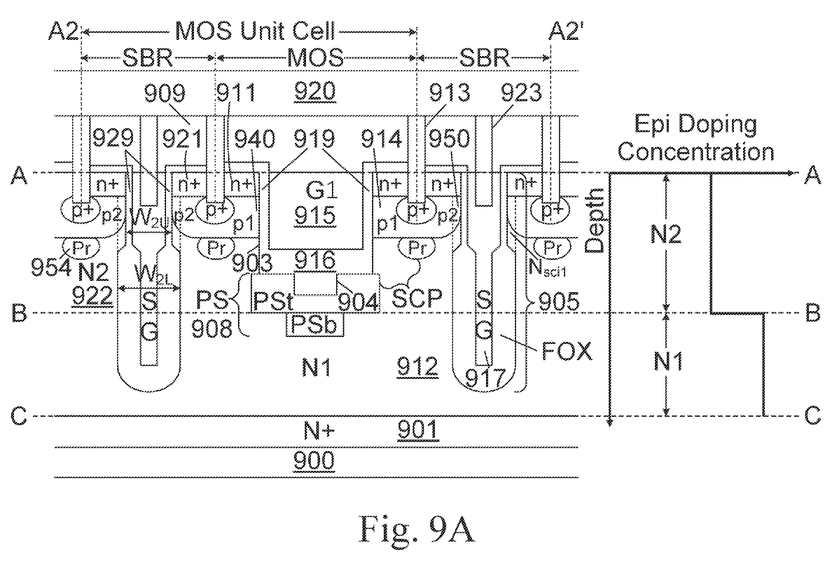

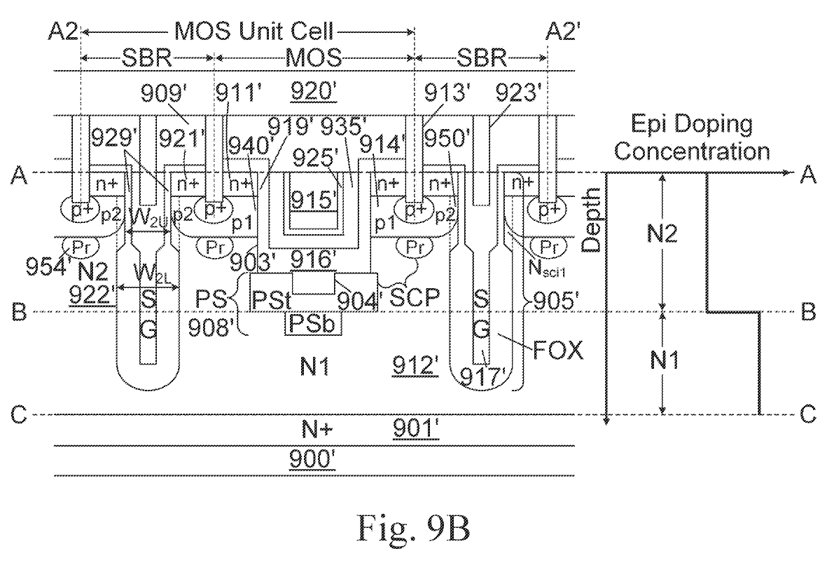

Please refer to FIG. 9A for a cross-sectional view showing another preferred embodiment along A2-A2’ line of FIG. 3A with a new and improved device structure having two stepped epitaxial layers wherein the doping concentration variations are depicted along the vertical direction according to the present invention. The N-channel trenched semiconductor power device has a similar structure to FIG. 5A, except that the present invention further comprises p type gate oxide electric field reducing (Pr, as illustrated) regions 954 as the second P-shield regions adjoining lower surfaces of the p1 body regions 914 and being apart from the first type and second type of gate trenches, forming a saturation current pitching (SCP, as illustrated) region with the first PS region 908 for the short circuit capability enhancement.

Please refer to FIG. 9B for a cross-sectional view showing another preferred embodiment along A2-A2’ line of FIG. 3A with a new and improved device structure having two stepped epitaxial layers wherein the doping concentration variations are depicted along the vertical direction according to the present invention. The N-channel trenched semiconductor power device has a similar structure to FIG. 9A, except that the gate electrode in the first top gate trench 903’ for the first SiC MOSFET (MOS, as illustrated) in this invention is a metal/poly (W/Ti-TiN/poly) stack gate electrode 915’/925’/935’ to increase switching speed and to reduce specific on-resistance.

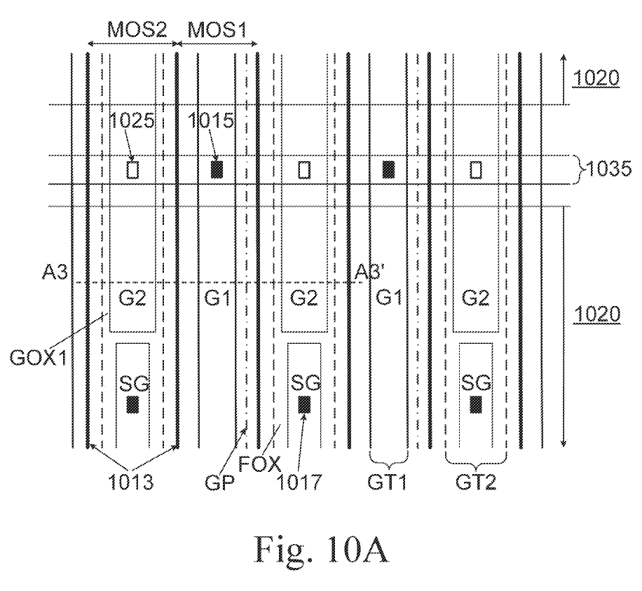

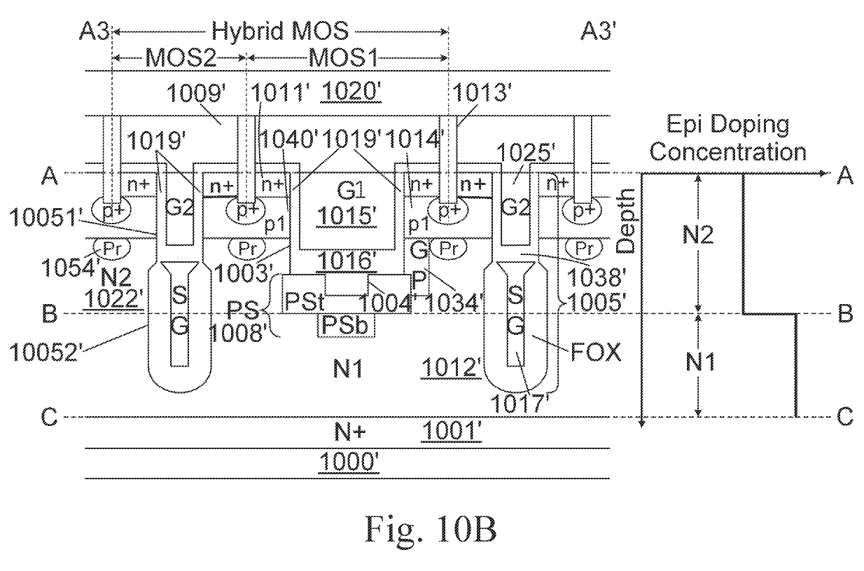

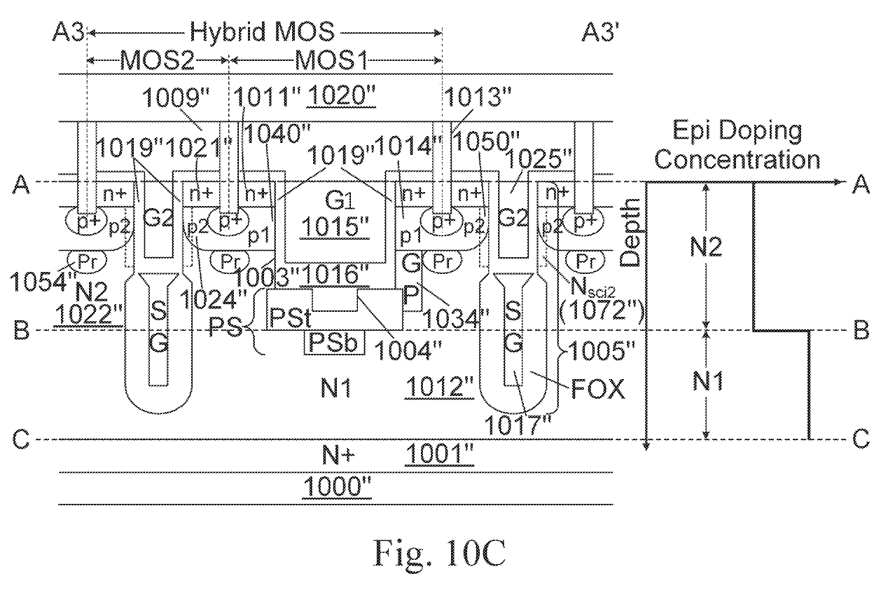

Please refer to FIG. 10A for a top view of another preferred embodiment for a trench semiconductor power device with stripe cells layout. The power device comprises a second MOSFET (MOS2, as illustrated) integrated with a first MOSFET (MOS1, as illustrated) to form a hybrid-channel MOSFET (HCMOSFET). In the present invention, a first gate electrode (G1, as illustrated) is formed in the first type of gate trenches (GT1, as illustrated), and two electrodes including a second gate electrode (G2, as illustrated) and a shielded gate electrode (SG, as illustrated) are formed in the second type of gate trenches (GT2, as illustrated), wherein the G1 in the GT1 and the G2 in the GT2 are shorted to a gate metal runner 1035 through a first gate contact 1015 and a second gate contact 1025, and the SG in the GT2 is shorted to a source metal 1020 through a shielded gate contact trench 1017. Moreover, the G2 is surrounded with a first gate oxide (GOX1, as illustrated) along sidewalls of an upper portion of the GT2, and the SG is surrounded with a first thick oxide (FOX, as illustrated) along sidewalls of a lower portion of the GT2, wherein the GOX1 has a thickness thinner than that of the FOX. Moreover, source contact trenches 1013 are disposed between the adjacent GT1 and GT2, and grounded P (GP, as illustrated) regions are formed surrounding a portion of sidewalls of the GT1 in each unit cell.

Please refer to FIG. 10B for a cross-sectional view showing a preferred embodiment along A3-A3’ line of FIG. 10A with a new and improved device structure having two stepped epitaxial layers wherein the doping concentration variations are depicted along the vertical direction according to the present invention. The N-channel trenched semiconductor power device has a similar structure to FIG. 2B, except for the different gate trench structure in the second type of gate trenches 1005’. In the present invention, a second MOSFET (MOS2, as illustrated) is integrated with a first MOSFET (MOS1, as illustrated) to form a hybrid-channel MOSFET (HCMOSFET). Inside each of the second type of gate trenches 1005’ of the MOS2, a second gate electrode (G2, as illustrated) 1025’ is disposed in the second top gate trench 10051’ above the shielded gate electrode (SG, as illustrated) 1017’ in the second bottom gate trench 10052’, and the G2 1025’ is isolated with the SG 1017’ by an inter-polysilicon oxide (IPO) layer 1038’. Moreover, the G2 1025’ is surrounded with a second gate oxide (GOX2) on sidewalls of the second top gate trench 1051’ with a thickness same as that of the GOX1 1019’. The present invention further comprises p type gate oxide electric field reducing (Pr, as illustrated) regions 1054’ as the second P-shield regions adjoining lower surfaces of the p1 body regions 1014’ and being apart from the first type and second type of gate trenches, and the N type epitaxial layer comprises two stepped epitaxial layers of different doping concentration including a bottom 1^{st} epitaxial layer (N1, as illustrated between B-B and C-C lines) 1012’ a with doping concentration D1 and a top 2^{nd} epitaxial layer (N2, as illustrated between A-A and B-B lines) 1022’ with a doping concentration D2, wherein D2< D1, to further reduce the specific on-resistance.

Please refer to FIG. 10C for a cross-sectional view showing another preferred embodiment along A3-A3’ line of FIG. 10A with a new and improved device structure having two stepped epitaxial layers wherein the doping concentration variations are depicted along the vertical direction according to the present invention. The N-channel trenched semiconductor power device has a similar structure to FIG. 10B, except that the present invention in FIG. 10C further comprises a second p body (p2, as illustrated) region 1024’’ of a second conductivity type along sidewalls of an upper portion of the second type of gate trench 1005’’ having a second n+ source region 1021’’ of a first conductivity type thereon, wherein the p2 body region 1024’’ has a doping concentration lower than that of the p1 body region 1014’’. A second channel region 1050’’ of the second MOSFET (MOS2, as illustrated) region is thus formed in the p2 body region 1024’’ along sidewalls of an upper portion of the second type of gate trench 1005’’ connecting to the second n+ source region 1021’’, while a first channel region 1040’’ of the first MOSFET (MOS1, as illustrated) region is formed in the p1 body region 1014’’ along sidewalls of the first top gate trench 1003’’, and the second channel region 1050’’ has a channel length shorter than that of the first channel region 1040’’. Moreover, the present invention further comprises a second short channel implant region (Nsci2, as illustrated) 1072’’ of a first conductivity type surrounding the second channel region 1050’’ with a doping concentration higher than that of the N type epitaxial layer 1002’’ to form two different threshold voltages of the hybrid-channel MOSFET comprising MOS1 and MOS2 with different threshold voltages to improve the positive temperature coefficient for reliability assurance operated at high temperatures, wherein a threshold voltage Vₜₕ₂ of MOS2 is lower than a threshold voltage Vₜₕ₁ of MOS1.

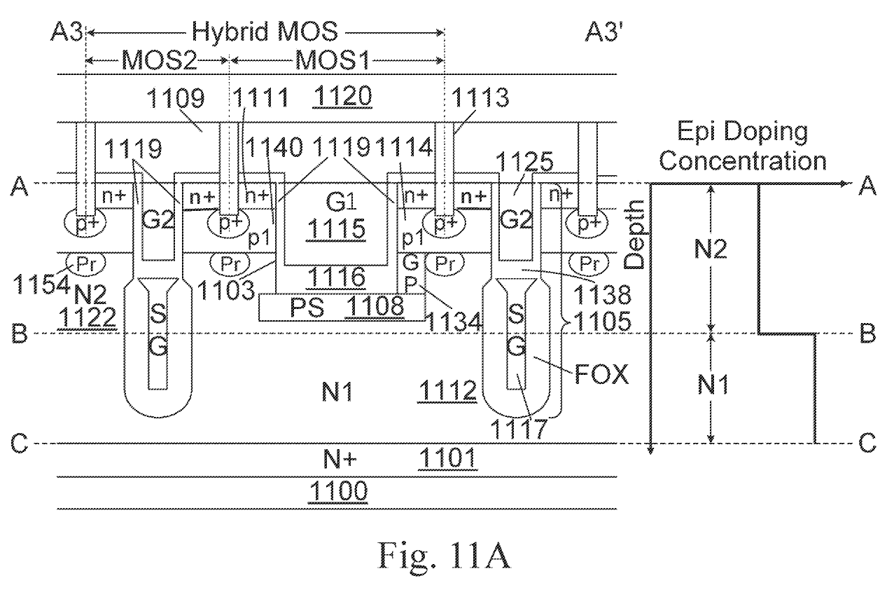

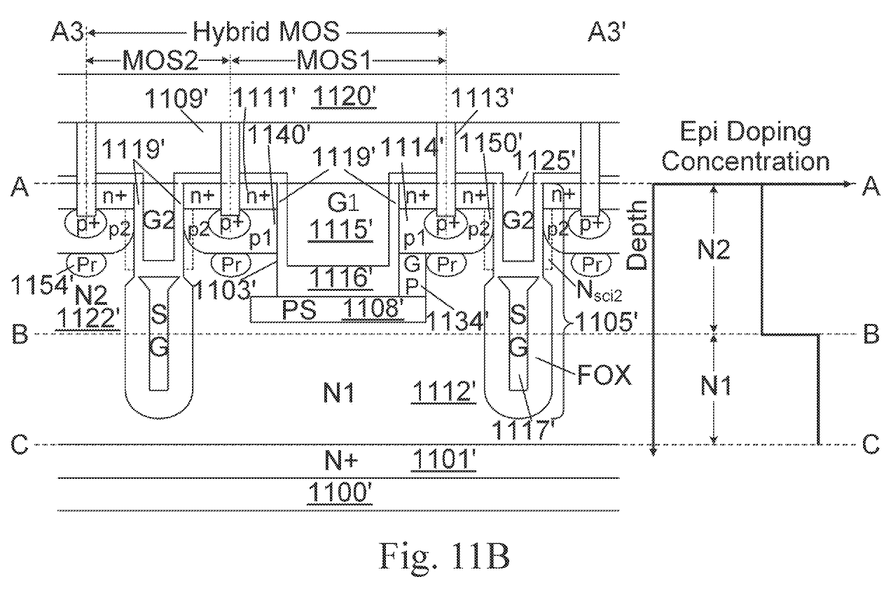

Please refer to FIG. 11A for a cross-sectional view showing another preferred embodiment along A3-A3’ line of FIG. 10A with a new and improved device structure having two stepped epitaxial layers wherein the doping concentration variations are depicted along the vertical direction according to the present invention. The N-channel trenched semiconductor power device has a similar structure to FIG. 10B, except that the first type of gate trench in the present invention comprises one single gate trench 1103, and a first P-shield (PS, as illustrated) region 1108 is formed surrounding a bottom of the first type of gate trench 1103 with a width greater than that of the first type of gate trench 1103.

Please refer to FIG. 11B for a cross-sectional view showing another preferred embodiment along A3-A3’ line of FIG. 10A with a new and improved device structure having two stepped epitaxial layers wherein the doping concentration variations are depicted along the vertical direction according to the present invention. The N-channel trenched semiconductor power device has a similar structure to FIG. 10C, except that the first type of gate trench in the present invention comprises one single gate trench 1103’, and a first P-shield (PS, as illustrated) region 1108’ is formed surrounding a bottom of the first type of gate trench 1103’ with a width greater than that of the first type of gate trench 1103’.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A power device having two types of gate trenches in each unit cell of a first Metal Oxide Semiconductor Field Effect Transistor (MOSFET) comprising:
an epitaxial layer of a first conductivity type grown on a substrate of said first conductivity type;
a first body region of a second conductivity type having a first source region of said first conductivity type thereon;
a first type of gate trench penetrating said first body region and said first source region and stopping in said epitaxial
layer;
said first type of gate trench having a first type of step trench structure comprising multiple step trenches including a first top gate trench and at least one first bottom gate trench; said first top gate trench is above said at least one first bottom gate trench with a trench width larger than that of said at least one first bottom gate trench;
a first gate electrode disposed in said first top gate trench surrounded with a first insulating film on a bottom region of said first top gate trench, and with a first gate oxide along sidewalls of said first top gate trench; said first insulating film having a thickness greater than that of said first gate oxide;
a first channel region of said first MOSFET formed in said first body region along at least one sidewall of said first top gate trench, connecting to said first source region;
a first P-shield (PS) region of said second conductivity type for gate oxide electric-field reduction surrounding said at least one first bottom gate trench filled up with said first insulating film;
said first PS region comprising at least two sub-PS regions including a first top PS region and a first bottom PS region, wherein said first bottom PS region is below said first top PS region, with a doping concentration lower than that of said top PS region;
at least one grounded P (GP) region of said second conductivity type surrounding a portion of sidewalls of said first type of gate trench, connecting with said first body region and said first PS region;
a shielded gate electrode disposed in a second type of gate trench; and
said first body and first source regions, and said shielded gate electrodes being shorted with a source metal through source contact trenches and shielded gate contact trenches respectively.

2. The power device of claim 1, wherein said shielded gate electrode is surrounded with a second insulating film on a bottom region and along sidewalls of said second type of gate trench, having a thickness greater than that of said first gate oxide.

3. The power device of claim 1, wherein said shielded gate electrode is surrounded with a second gate oxide along sidewalls of an upper portion of said second type of gate trench, and with a second insulating film along a lower portion of said second type of gate trench; said second gate oxide has a thickness less that of said first gate oxide, and said second insulating film has a thickness greater than that of said first gate oxide;
a second body region of said second conductivity type having a second source region of said first conductivity type thereon, with a doping concentration lower than that of said first body region;
a second channel region of a Super Barrier Rectifier (SBR) formed in said second body region along at least one sidewall of said upper portion of said second type of gate trench, connecting to said second source region;
said first and second body regions, said first and second source regions, and said shielded gate electrodes being shorted to a source metal through source contact trenches and shielded gate contact trenches; and
said SBR integrated with said first MOSFET in said each unit cell.

4. The power device of claim 3, wherein said second type of gate trench has a second type of step trench structure with a narrower gate trench width in said upper portion than in said lower portion of said second type of gate trench, and said second insulating film is formed by Local Oxidation of Silicon (LOCOS).

5. The power device of claim 1, further comprising a second PS region of said second conductivity type adjoining a lower surface of said first body region, forming a saturation current pitching (SCP) region with said first PS region for the short circuit capability enhancement.

6. The power device of claim 3, further comprising a first short channel implant (SCI1) region of said first conductivity type surrounding said second channel region, wherein said SCI1 region is formed by Arsenic or Phosphorus angle implantation along sidewalls of said upper portion of said second type of gate trench, and having a doping concentration higher than that of said epitaxial layer; said second channel region has a channel length shorter than that of said first channel region.

7. The power device of claim 1, further comprising a second gate electrode disposed in said upper portion of said second type of gate trench above said shielded gate electrode in said lower portion of said second type of gate trench, and isolated with said shielded gate electrode with an inter-polysilicon oxide (IPO) layer;
said second gate electrode surrounded with a second gate oxide on sidewalls of said upper portion of said second type of gate trench;
a second body region of said second conductivity type having a second source region of said first conductivity type thereon;
said second type of gate trench penetrating said second body region and said second source region and stopping in said epitaxial layer; and
a second channel region of a second MOSFET further formed in said second body region along said sidewalls of said upper portion of said second type of gate trench connecting to said second source region; and
said second MOSFET forming a hybrid-channel MOSFET with said first MOSFET in said each unit cell.

8. The power device of claim 7, wherein said second body region has a doping concentration same as that of said first body region.

9. The power device of claim 7, further comprising a second short channel implant (SCI2) region of said first conductivity type surrounding said second channel region, wherein said SCI2 region has a doping concentration higher than that of said epitaxial layer; said second channel region has a channel length shorter than that of said first channel region; and said second body region along sidewalls of said upper portion of said second type of gate trench has a doping concentration lower than that of said first body region.

10. The power device of claim 1, wherein said epitaxial layer is a single epitaxial layer with a uniform doping concentration.

11. The power device of claim 1, wherein said epitaxial comprises at least two stepped epitaxial layers of different doping concentrations including a bottom epitaxial layer with a doping concentration D1 and a top epitaxial layer above said bottom epitaxial layer with a doping concentration D2, wherein said D2 < said D1.

12. The power device of claim 11, further comprising a buffer epitaxial layer between said substrate and said bottom epitaxial layers having a doping concentration DB, wherein said DB < said D2 < said D1.

13. The power device of claim 11, further comprising a buffer epitaxial layer between said substrate and said bottom epitaxial layer having a doping concentration DB, wherein said D2 < said DB < said D1.

14. The power device of claim 1, further comprising an electric field reducing region of said first conductivity type surrounding said bottom region of said second type of gate trench with a doping concentration lower than said epitaxial layer.

15. The power device of claim 1, wherein said first type and second type of gate trenches have a square or stripe shape.

16. The power device of claim 3, wherein said SBR has a square shape, and surrounded by said first MOSFET.

17. The power device of claim 1, wherein said first gate electrode is composed of Tungsten, Titanium, Titanium Nitride and Polysilicon stack layers.

18. A power device having two types of gate trenches in each unit cell of a first MOSFET comprising:
an epitaxial layer of a first conductivity type grown on a substrate of said first conductivity type;
a first body region of a second conductivity type having a first source region of said first conductivity type thereon;
a first type of gate trench penetrating said first body region and said first source region and stopping in said epitaxial layer;
a first gate electrode disposed in said first type of gate trench and surrounded with a first gate oxide along sidewalls and with a first insulating layer on a bottom region of said first type of gate trench; and said first insulating layer having a thickness greater than that of said first gate oxide;
a first P-shield (PS) region of said second conductivity type for the gate oxide electric-field reduction disposed below said first type of gate trench;
a second PS region of said second conductivity type adjoining a lower surface of said first body region, forming a saturation current pitching (SCP) region with said first PS region for the short circuit capability enhancement;
at least one grounded P (GP) region of said second conductivity type surrounding a portion of sidewalls of said first type of gate trench, connecting with said first body region and said first PS region;
a first channel region of a first MOSFET formed in said first body region along sidewalls of said first type of gate trench, connecting to said first source region;
a second type of gate trench formed in said epitaxial layer having a step trench structure with a narrower trench width in an upper portion than in a lower portion of said second type of gate trench, and said second type of gate trench having a trench depth deeper than that of said first type of gate trench; and
a first shielded gate electrode disposed in at least said lower portion of said second type of gate trench surrounded with a second insulating film on a bottom region and along sidewalls of said second bottom gate trench as a field oxide; said second insulating film having a thickness greater than that of said first gate oxide;
said first body and said first source regions, and said shielded gate electrodes being shorted to a source metal through source contact trenches and shielded gate contact trenches, respectively.

19. The power device of claim 18, wherein said first shielded gate electrode disposed in said second type of gate trench is surrounded with a second gate oxide along sidewalls of said upper portion of said second type gate trench; and said second gate oxide having a thickness less than that of said first gate oxide;
said power device further comprising a second body region of said second conductivity type having a second source region of said first conductivity type thereon; and said second body region along sidewalls of said upper portion of said second type of gate trench having a doping concentration lower than that of said first body region;
said second type of gate trench penetrating said second body region and said second source region and stopping in said epitaxial layer;
a second channel region of a super barrier rectifier (SBR) formed in said second body region along sidewalls of said upper portion of said second type of gate trench, connecting to said second source region;
a first short channel implant (SCI1) region of said first conductivity type surrounding said second channel region, and having a doping concentration higher than that of said epitaxial layer; said second channel region has a channel length shorter than that of said first channel region; and
said SBR integrated with said first MOSFET in said each unit cell.

20. The power device of claim 18, further comprising a second gate electrode disposed in said upper portion of said second type of gate trench above said shielded gate electrode in said lower portion of said second type of gate trench, and isolated with said shielded gate electrode with an inter-polysilicon oxide (IPO) layer;
said second gate electrode surrounded with a second gate oxide along sidewalls of said upper portion of said second type of gate trench;
a second body region of said second conductivity type having a second source region of said first conductivity type thereon; and said second body region having a doping concentration lower than that of said first body region.
said second type of gate trench penetrating said second body region and said second source region and stopping in said epitaxial layer; and
a second channel region of a second MOSFET further formed in said second body region along said sidewalls of said upper portion of said second type of gate trench, connecting to said second source region;
a second short channel implant (SCI2) region of said first conductivity type surrounding said second channel region, wherein said SCI2 region has a doping concentration higher than that of said epitaxial layer; said second channel region has a channel length shorter than that of said first channel region; and said second body region along sidewalls of said upper portion of said second type of gate trench has a doping concentration lower than that of said first body region; and
said second MOSFET forming a hybrid-channel MOSFET with said first MOSFET in said each unit cell.
